(19) United States
(12) Patent Application Publication
(10) Pub. No.: US 2025/0006822 A1
(43) Pub. Date: Jan. 2, 2025

(54) METHOD FOR MANUFACTURING GATE-ALL-AROUND TFET DEVICE

(71) Applicant: INSTITUTE OF MICROELECTRONICS, CHINESE ACADEMY OF SCIENCES, Beijing (CN)

(72) Inventors: Na Zhou, Beijing (CN); Junjie Li; Jianfeng Gao, Beijing (CN); Tao Yang, Beijing (CN); Junfeng Li, Beijing (CN); Jun Luo, Beijing (CN)

(21) Appl. No.: 18/708,028

(22) PCT Filed: Nov. 27, 2023
(86) PCT No.: PCT/CN2023/134341

§ 371 Date: May 7, 2024

(30) Foreign Application Priority Data
Nov. 30, 2022 (CN) 202211533675.3

(51) Int. Cl. H01L 29/66; H01L 29/06; H01L 29/423; H01L 29/775; H01L 29/786

(52) U.S. Cl. CPC H01L 29/66977; H01L 29/0673; H01L 29/42392; H01L 29/66439; H01L 29/66545; H01L 29/66553; H01L 29/6656; H01L 29/775; H01L 29/78696

(57) ABSTRACT

A method for manufacturing a gate-all-around TFET device. The method comprises: forming, on a substrate, a channel stack comprising channel layer(s) and sacrificial layer(s) that alternate with each other; forming, on the substrate, a dummy gate astride the channel stack; forming a first spacer at a surface of the dummy gate; etching the sacrificial layer(s) to form recesses on side surfaces of the channel stack; forming second spacers in the recesses, respectively; fabricating a source and a drain separately, where a region for fabricating the source is shielded by a dielectric material when fabricating the drain, and a region for fabricating the drain is shielded by another dielectric material when fabricating the source; etching the dummy gate and the sacrificial layer(s) to form a space for a surrounding gate; and fabricating a surrounding dielectric-metal gate in the space.

This application claims priority to Chinese Patent Application No. 202211533675.3, titled “METHOD FOR MANUFACTURING GATE-ALL-AROUND TFET DEVICE”, filed on Nov. 30, 2022 with the China National Intellectual Property Administration, which is incorporated herein by reference in its entirety.

### FIELD

The present disclosure relates to the technical field of manufacture of semiconductor devices, and in particular to a method for manufacturing a gate-all-around TFET device.

### BACKGROUND

Conventional structures of fin field-effect transistor (FinFET) devices face many challenges in techniques for sub-5 nm integrated circuits. Gate-all-around nanowire devices are considered to be key architecture for following the Moore's Law, because they are advantageous in aspects such as channel electrostatic integrity, leakage current control, and one-dimensional ballistic propagation of carriers. In recent years, combining ideal gate-all-around nanowire structures with mainstream FinFET techniques to develop next-generation integration technology has become a research hotspot for boosting development of integrated circuits.

Although performances of devices under advanced process nodes have been significantly improved compared over the recent years, gate-all-around devices still suffers from a problem of high power consumption due to increased difficulty in further reducing a supply voltage, increased leakage current of devices, 60 mV/Dec limitation on a sub-threshold swing, and other factors. The leakage current of a device under an off-state may be decreased through reducing the sub-threshold swing. Tunneling field-effect transistors (TFETs) are capable to break the limitation on the sub-threshold swing, because they operate under a conduction mechanism of band-to-band tunneling (BTBT) rather than thermionic emission adopted in traditional MOSFETs. Hence, the TEFTs can achieve quite small leakage current in the off-state. There are still great challenges in how to fabricate TFET devices which are compatible with mainstream gate-all-around nanowire techniques.

### SUMMARY

A method for manufacturing a gate-all-around tunneling field-effect transistor (TFET) device is provided according to embodiments of the present disclosure. Manufacture of the TFET device is compatible with techniques for manufacturing gate-all-around devices, and hence mass production of gate-all-around TFET devices is feasible.

A method for manufacturing a gate-all-around TFET device is provided according to an embodiment of the present disclosure. The method comprises: forming, on a substrate, a channel stack comprising at least one channel layer and at least one sacrificial layer that alternate with each other: forming, on the substrate, a dummy gate astride the channel stack: forming a first spacer at a surface of the dummy gate: etching the at least one sacrificial layer to form recesses on side surfaces of the channel stack: forming second spacers in the recesses, respectively: fabricating a source and a drain separately, where a region for fabricating the source is shielded by a dielectric material when fabricating the drain, and a region for fabricating the drain is shielded by another dielectric material when fabricating the source: etching the dummy gate and the at least one sacrificial layer to form a space for a surrounding gate; and fabricating a surrounding dielectric-metal gate in the space to form the gate-all-around TFET device.

In an embodiment, forming, on the substrate, the channel stack comprising the at least one channel layer and the at least one sacrificial layer that alternate with each other comprises: growing, on a silicon-on-insulator substrate through epitaxy, at least one layer of silicon germanium and at least one layer of boron-doped silicon that alternate with each other, where the at least one layer of silicon germanium serves as the at least one sacrificial layer, and the at least one layer of boron-doped silicon serves as the at least one channel layer; and dry-etching the channel stack to form the channel stack which is a fin extending along a first direction.

In an embodiment, forming, on the substrate, the dummy gate astride the channel stack comprises: forming a first film covering a surface of the substrate and the channel stack; and etching the first film according to a pattern of the channel stack to form the dummy gate, where the dummy gate and the channel stack form a stepped structure along a first direction, and the dummy gate extends across the channel stack along a second direction.

In an embodiment, forming the first spacer at the surface of the dummy gate comprises: forming a second film which covers the dummy gate, the channel stack, and the substrate, where etching selectivity between the second film and the first film is not equal to 1: etching the second film to form the first spacer covering side surfaces and a top surface of the dummy gate, where the first spacer is aligned with the side surfaces of the channel stack along the first direction.

In an embodiment, etching the at least one sacrificial layer to form the recesses on the side surfaces of the channel stack comprises: etching exposed sidewalls of the at least one sacrificial layer inward to form the recesses, where a depth of each of the recesses is equal to a thickness of the first spacer.

In an embodiment, forming the second spacers within the recesses comprises: forming a third film of which a thickness is more than or equal to the depth of the recesses; and etching the third film to form the second spacers, where the second spacers are aligned with the at least one channel layer along the first direction.

In an embodiment, fabricating the source and the drain separately comprises: forming a second film: etching the second film to expose a top surface of the substrate in the region for fabricating the source: growing the source, which is in-situ doped, through epitaxy on the top surface of the substrate; and removing the second film in the region for fabricating the drain.

In an embodiment, fabricating the source and the drain separately comprises: forming a second film: etching the second film to expose a top surface of the substrate in the region for fabricating the drain: growing the drain, which is in-situ doped, through epitaxy on the top surface of the substrate; and removing the second film in the region for fabricating the source.

In an embodiment, etching the dummy gate and the at least one sacrificial layer to form the space for the surrounding gate comprises: removing the second film over the dummy gate through planarization to expose a top surface of the dummy gate: removing the dummy gate through wet-etching to expose the at least one sacrificial layer; and removing the at least one sacrificial layer through chemical etching or atomic-layer etching to form the space.

In an embodiment, fabricating the surrounding dielectric-metal gate in the space to form the gate-all-around TFET device comprises: forming the surrounding dielectric-metal gate in the space through atomic layer deposition or vapor deposition.

Herein a predecessor structure of the TFET device is provided through arrangement of the channel stack and coordination between the dummy gate and the sacrificial layer(s). During processing the regions for fabricating the source and the drain, the region for fabricating the drain is shielded when fabricating the source, while the region for fabricating the source is shielded when preparing the drain. Thereby, the source and the drain of the TFET device can be fabricated. Afterwards, the dummy gate and sacrificial layer(s) are removed, and the dielectric-metal gate is formed, so as to fabricate the surrounding gate for the channel layer(s) between the source and the drain. Such solution renders manufacture techniques of gate-all-around devices adaptable to TFET devices. Mass production of gate-all-around TFET devices can be achieved with effectively improved efficiency.

### BRIEF DESCRIPTION OF THE DRAWINGS

FIG. 1 is a flow chart of a method for manufacturing a gate-all-around tunneling field-effect transistor (TFET) device according to an embodiment of the present disclosure.

FIG. 2 is a flow chart of a process of forming a channel stack when manufacturing a gate-all-around TFET device according to an embodiment of the present disclosure.

FIG. 3 is a flow chart of forming a dummy gate when manufacturing a gate-all-around TFET device according to an embodiment of the present disclosure.

FIG. 4 is a flow chart of forming a first spacer when manufacturing a gate-all-around TFET device according to an embodiment of the present disclosure.

FIG. 5 is a flow chart of forming second spacers when manufacturing a gate-all-around TFET device according to an embodiment of the present disclosure.

FIG. 6 is a flow chart of fabricating a source when manufacturing a gate-all-around TFET device according to an embodiment of the present disclosure.

FIG. 7 is a flow chart for fabricating a drain when manufacturing a gate-all-around TFET device according to an embodiment of the present disclosure.

FIG. 8 is a flow chart of etching a dummy gate and a sacrificial layer when manufacturing a gate-all-around TFET device according to an embodiment of the present disclosure.

FIG. 9 is a schematic structural diagram after a sacrificial layer and a channel layer are formed when manufacturing a gate-all-around TFET device according to an embodiment of the present disclosure.

FIG. 10 is a schematic structural diagram after a channel stack is formed when manufacturing a gate-all-around TFET device according to an embodiment of the present disclosure.

FIG. 11 is a schematic structural diagram after a dummy gate and a first spacer are formed when manufacturing a gate-all-around TFET device according to an embodiment of the present disclosure.

FIG. 12 is a schematic structural diagram after recesses are formed when manufacturing a gate-all-around TFET device according to an embodiment of the present disclosure.

FIG. 13 is a schematic structural diagram after second spacers are formed when manufacturing a gate-all-around TFET device according to an embodiment of the present disclosure.

FIG. 14 is a schematic structural diagram of shielding on a region for fabricating a drain when manufacturing a gate-all-around TFET device according to an embodiment of the present disclosure.

FIG. 15 is a schematic structural diagram after a source is fabricated when manufacturing a gate-all-around TFET device according to an embodiment of the present disclosure.

FIG. 16 is a schematic structural diagram of shielding on a region for fabricating a source when manufacturing a gate-all-around TFET device according to an embodiment of the present disclosure.

FIG. 17 is a schematic structural diagram after a drain is fabricated when manufacturing a gate-all-around TFET device according to an embodiment of the present disclosure.

FIG. 18 is a schematic structural diagram after a dummy gate is etched when manufacturing a gate-all-around TFET device according to an embodiment of the present disclosure.

FIG. 19 is a schematic structural diagram after a sacrificial layer is etched when manufacturing a gate-all-around TFET device according to an embodiment of the present disclosure.

FIG. 20 is a schematic structural diagram after a dielectric-metal gate is formed when manufacturing a gate-all-around TFET device according to an embodiment of the present disclosure.

FIG. 21 is a schematic structural diagram after a metal plug is formed when manufacturing a gate-all-around TFET device according to an embodiment of the present disclosure.

### DETAILED DESCRIPTION OF EMBODIMENTS

In order to clarify objectives, technical solutions and advantages of embodiments of the present disclosure, hereinafter technical solutions of the present disclosure would be clearly and completely described in conjunction with the drawings for the embodiments. Apparently, the described embodiments are only some rather than all embodiments of the present disclosure. All other embodiments obtained by those skilled in the art on a basis of those provided herein without creative efforts shall fall within the protection scope of the present disclosure.

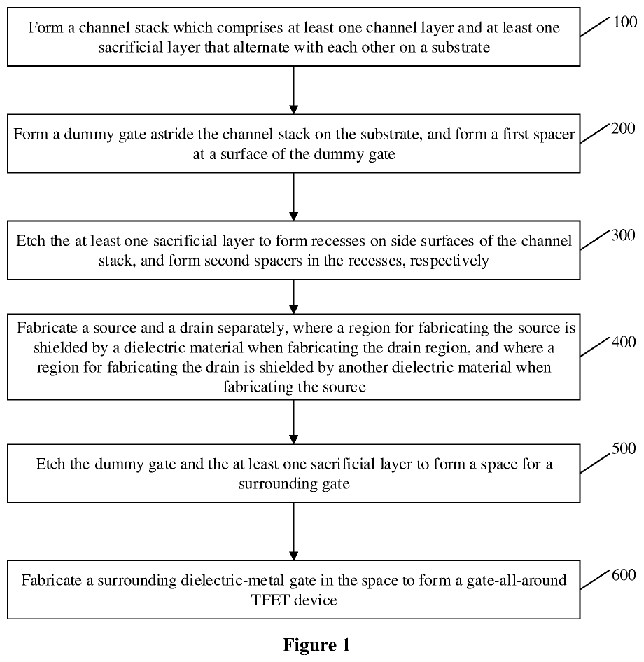

A method for manufacturing a gate-all-around tunneling field-effect transistor (TFET) device is provided according to an embodiment of the present disclosure. As shown in FIG. 1, the method comprises following steps 100 to 600.

In step 100, a channel stack which comprises at least one channel layer and at least one sacrificial layer that alternate with each other is formed on a substrate.

In some embodiments, the substrate refers to a structure that supports a semiconductor device. Herein the substrate may be a silicon-on-insulator substrate, or may be another substrate. The channel layer refers to a material film which would serve as a channel after the device has been formed. The sacrificial layer refers to a material film which would be removed when manufacturing the device. In this step, it may be a channel layer that is first formed on the substrate, or may be a sacrificial layer that is first formed on the substrate. In an embodiment, the channel layer is a lightly n-doped silicon film, which can meet a requirement on the channel layer of the TFET device.

In step 200, a dummy gate astride the channel stack is formed on the substrate, and a first spacer is formed at a surface of the dummy gate.

In some embodiments, the dummy gate refers to a material film formed in a region corresponding to a gate and serving as a placeholder for reserving a space for the gate. In subsequent steps, the dummy gate would be removed before forming the gate, and the space form after the removal is utilized for forming the gate. The dummy gate astride the channel stack refers to that an extending direction of the dummy gate is perpendicular to an extending direction of the channel stack, and that the dummy gate is in contact with two opposite lateral surfaces and a top surface of the channel stack along its extending direction. Forming the first spacer at the surface the dummy gate refer to forming the first spacer(s) covering the dummy gate, and the first spacer(s) may cover lateral surfaces and a top surface of the dummy gate.

In step 300, the at least one sacrificial layer is etched to form recesses on side surfaces of the channel stack, and second spacers are formed in the recesses, respectively.

In some embodiments, exposed sidewalls of the sacrificial layer are etched inward when etching the sacrificial layer. After the sacrificial layer has been etched, a part of the sacrificial layer(s) is removed, and recesses would be formed on the side surfaces of the channel stack at positions corresponding to the sacrificial layer(s). Forming the second spacers refers to that the recesses are filled so that each side surface of the channel stack is flat again. A filling material may be one or a combination of SiC, Si₃N₄, and SiON. Since the space occupied by the sacrificial layer(s) is configured to fabricate a surrounding gate subsequently, the second spacers have two functions: limiting a size of the surrounding gate, and insulating the surrounding gate from a source and a drain.

In step 400, a source and a drain are fabricated separately, where a region for fabricating the source is shielded by a dielectric material when fabricating the drain, and where a region for fabricating the drain is shielded by another dielectric material when fabricating the source.

In some embodiments, the source and the drain of the TFET device have different characteristics, and hence the source and drain need to be fabricated separately. When fabricating the source, a drain region needs to be covered for protecting the drain against contamination of a source material. Similarly, when fabricating the drain, a source region needs to be covered for protecting the source against contamination of a drain material. Since the side surfaces of the channel layer(s) are exposed when fabricating the source or the drain, the channel layer(s) would be in contact with the source or the drain.

In step 500, the dummy gate and the at least one sacrificial layer are etched to form a space for a surrounding gate.

In some embodiments, since the dummy gate and the at least one sacrificial layer occupy the space for forming the surrounding gate, the dummy gate and the at least one sacrificial layer need to be removed before forming the surrounding gate. During the removal, the dummy gate and the at least one sacrificial layer may be removed in separate etching processes since the may have different characteristics in etching.

In step 600, a surrounding dielectric-metal gate is fabricated in the space, so as to form the gate-all-around TFET device.

In some embodiments, after the at least one sacrificial layer and the dummy gate are removed, the space once occupied by the at least one sacrificial layer and the dummy gate is vacant, and hence the surrounding gate can be formed in such space. Since the dummy gate and the sacrificial layer(s) form a structure wrapping the channel layer(s), the vacant space surrounds the channel layer(s), and the dielectric layer and the metal layer also surround the channel layer(s) after being formed. Thereby, the surrounding gate is formed. In some embodiments, the dielectric layer may be made a high-material, such as HfO₂, ZrO₂, Al₂O₃, or the like.

In embodiments of the present disclosure, a predecessor structure of the TFET device is provided through arrangement of the channel stack and coordination between the dummy gate and the sacrificial layer(s). During processing the regions for fabricating the source and the drain, the region for fabricating the drain is shielded when fabricating the source, while the region for fabricating the source is shielded when preparing the drain. Thereby, the source and the drain of the TFET device can be fabricated. Afterwards, the dummy gate and sacrificial layer(s) are removed, and the dielectric-metal gate is formed, so as to fabricate the surrounding gate for the channel layer(s) between the source and the drain. Such solution renders manufacture techniques of gate-all-around devices adaptable to TFET devices. Mass production of gate-all-around TFET devices can be achieved with effectively improved efficiency.

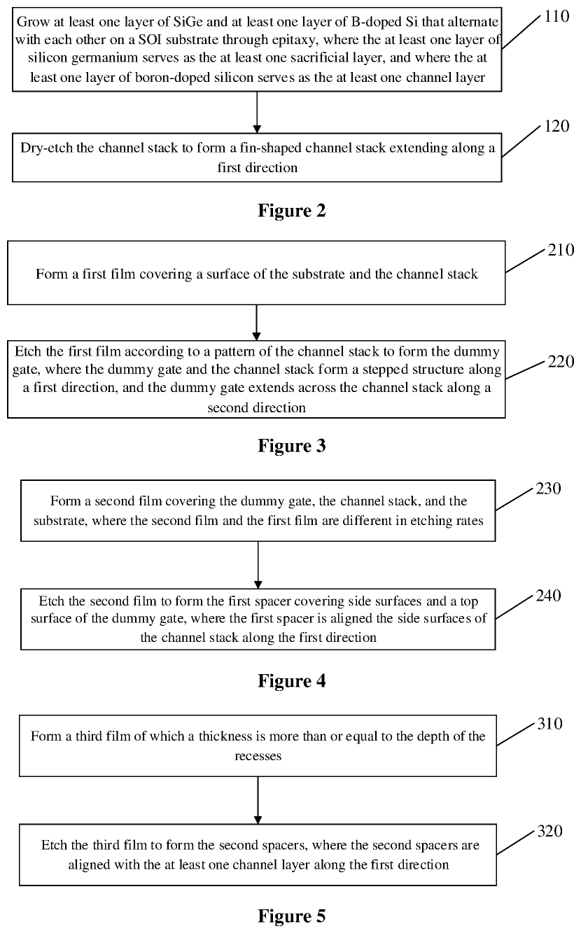

Reference is made to FIG. 2. In an embodiment, forming, on the substrate, the channel stack comprising the at least one channel layer and the at least one sacrificial layer that alternate with each other comprises following steps 110 and 120.

In step 110, at least one layer of silicon germanium and at least one layer of boron-doped silicon that alternate with each other are grown on a silicon-on-insulator substrate through epitaxy, where the at least one layer of silicon germanium serves as the at least one sacrificial layer, and where the at least one layer of boron-doped silicon serves as the at least one channel layer.

In some embodiments, a silicon film may serve as the channel layer due to a characteristic compatible with the channel. A silicon germanium film may exhibit a different etching rate from the silicon film during the etching, and hence it is convenient to remove the silicon germanium film while retaining the silicon film during the etching.

In step 120, the channel stack is subject to dry etching, and accordingly the fin-shaped channel stack extending along a first direction is formed.

In some embodiments, the channel stack is initially formed on an entire surface of the substrate during the epitaxy, and needs to be etched to form a fin-shape for manufacture the device. The fin-shaped channel stack facilitates forming the dummy gate astride the channel stack.

Reference is made to FIG. 3. In an embodiment, forming the dummy gate astride the channel stack on the substrate comprises following steps 210 and 220.

In step 210, a first film covering a surface of the substrate and the channel stack is formed.

In some embodiments, the first film is formed to cover the substrate and the channel stack. In such process, a conformal structure extending from the surface of the substrate to a surface of the channel stack is formed, and the conformal structure covers sidewall(s) of the channel stack.

In step 220, the first film is etched according to a pattern of the channel stack to form the dummy gate, where the dummy gate and the channel stack form a stepped structure along a first direction, and the dummy gate extends across the channel stack along a second direction.

In some embodiments, along the first direction, a dimension of the first film remained after the etching is smaller than a dimension of the channel stack. Thereby, the stepped structure ascending from the channel stack to the first film is formed. Along the second direction, a dimension of remaining first film is larger than a dimension of the channel stack. Thereby, the dummy gate is astride the channel stack. A central axis of the dummy gate and a central axis of the channel stack may be aligned with each other in both the first direction and the second direction.

Reference is made to FIG. 4. In an embodiment, forming the first spacer at the surface of the dummy gate comprises following steps 230 and 240.

In step 230, a second film covering the dummy gate, the channel stack, and the substrate, is formed, where the second film and the first film are different in etching rates.

In some embodiments, the second film is formed to cover a surface of the dummy gate, the channel stack, and the substrate, such that a conformal structure is formed. The second film covers side surfaces of the dummy gate and side surfaces of the channel stack. The second film and the first film have different etching rates, such that etching on the dummy gate would not damage the second film, that is, the first spacer. Subsequent formation of the surrounding gate is facilitated.

In step 240, the second film is etched to form the first spacer covering side surfaces and a top surface of the dummy gate, where the first spacer is aligned the side surfaces of the channel stack along the first direction.

In some embodiments, along the first dimension, the second film remaining after the etching is aligned with the side surfaces of the channel stack along the first direction. Thereby, the side surfaces of the channel stack are exposed, and the recesses can be formed through etching the sacrificial layer(s) in subsequent steps. Moreover, since the dimension of the dummy gate is smaller than that of the channel stack along the first direction, the remaining second film at the two side surfaces of the dummy gate, which are perpendicular to the first direction, has sufficient thickness to form the first spacer.

In an embodiment, etching the at least one sacrificial layer to form the recesses on the side surfaces of the channel stack comprises a following step. Exposed sidewalls of the at least one sacrificial layer are etched inward to form the recesses, where a depth of each recess is equal to a thickness of the first spacer.

Herein the surrounding gate occupies the space previously occupied by the dummy gate and the sacrificial layer(s). Configuring a depth of the etching to be equal to the thickness of the first spacer facilitates forming the surrounding gate having a uniform dimensions along the first direction.

Reference is made to FIG. 5. In an embodiment, forming the second spacers within the recesses comprises following steps 310 and 320.

In step 310, a third film of which a thickness is more than or equal to the depth of the recesses is formed.

In some embodiments, when being formed, the third film covers a top surface of all components that have been formed, so as form a conformal structure covering a surface of the entire current structure. The thickness of the third film is configured to be more than or equal to a depth of the recess, such that the recess can be fully filled.

In step 320, the third film is etched to form the second spacers, where the second spacers are aligned with the at least one channel layer along the first direction.

In some embodiments, when etching the third film, all the portion of the third film located outside the recesses is removed, and only the portion the third film located inside the recesses is retained as the second spacers.

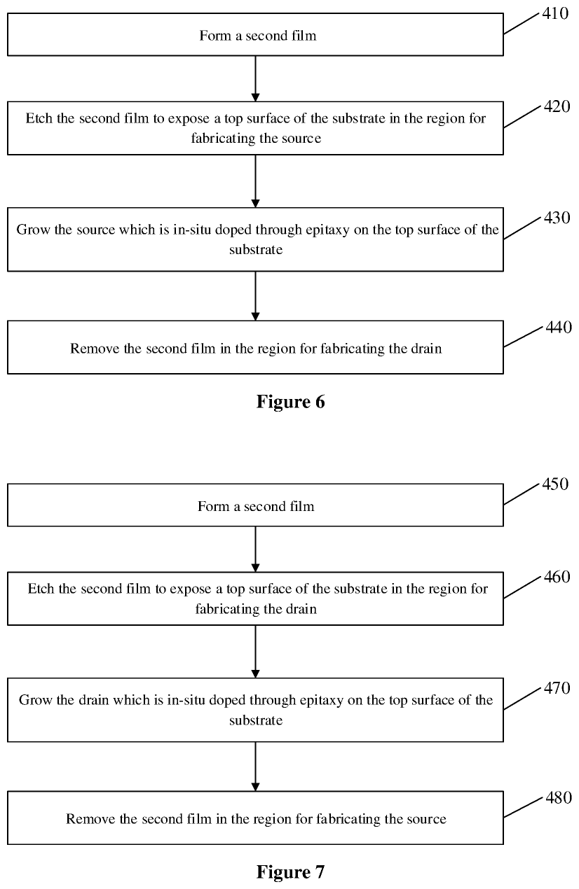

Reference is made to FIG. 6. In some embodiments, fabricating the source while shielding the region for fabricating the drain comprises following steps 410 to 450.

In step 410, a second film is formed.

In some embodiments, the second film which has been formed overs the region for fabricating the source, the region for fabricating the drain, and the dummy gate.

In step 420, the second film is etched to expose a top surface of the substrate in the region for fabricating the source.

In some embodiments, the second film needs to be etched for fabricating the source, so as to expose the top surface of the substrate. Thereby, the source is in contact with the channel layer. During the etching, only the second film in the region for fabricating the source may be etched. Alternatively, the second film in all regions except the region for fabricating the drain may be removed.

In step 430, the source which is in-situ doped is grown through epitaxy on the top surface of the substrate.

In some embodiments, the sidewall of the channel layer(s) may be further exposed after the substrate is exposed, and then the source is fabricated on the substrate. Thereby, the source can be in contact with the channel layer(s).

In step 440, the second film in the region for fabricating the drain is removed.

In some embodiments, the drain needs to be prepared subsequently after the source has been fabricated. Hence, the second film in the region for fabricating the drain needs to be removed. Since the second film may be further deposited when fabricating the drain, the second film in the region for fabricating the drain region may be not immediately removed after fabricating the source as an alternative. In such case, the second film in the region for fabricating the drain may be removed after a film for shielding the source has been formed.

Reference is made to FIG. 7. In some embodiments, fabricating the drain while shielding the region for fabricating the source comprises following steps 440 to 480.

In step 450, a second film is formed.

In some embodiments, the second film which has been formed overs the region for fabricating the source, the region for fabricating the drain, and the dummy gate.

In step 460, the second film is etched to expose a top surface of the substrate in the region for fabricating the drain.

In some embodiments, the second film needs to be etched for fabricating the drain, so as to expose the top surface of the substrate. Thereby, the drain is in contact with the channel layer. During the etching, only the second film in the region for fabricating the drain may be etched. Alternatively, the second film in all regions except the region for fabricating the source may be removed.

In step 470, the drain which is in-situ doped is grown through epitaxy on the top surface of the substrate.

In some embodiments, the sidewall of the channel layer(s) may be further exposed after the substrate is exposed, and then the drain is fabricated on the substrate. Thereby, the drain can be in contact with the channel layer(s).

In step 480, the second film in the region for fabricating the source is removed.

In some embodiments, after fabricating the drain, the second film for shielding the source may be contaminated. Hence, the second film in the region for fabricating the source needs to be removed to prevent the contamination deteriorates the device. It is appreciated that such second film may be retained in a case that a degree of the contamination is acceptable, such that fewer materials are consumed when forming a film filling in a subsequent step.

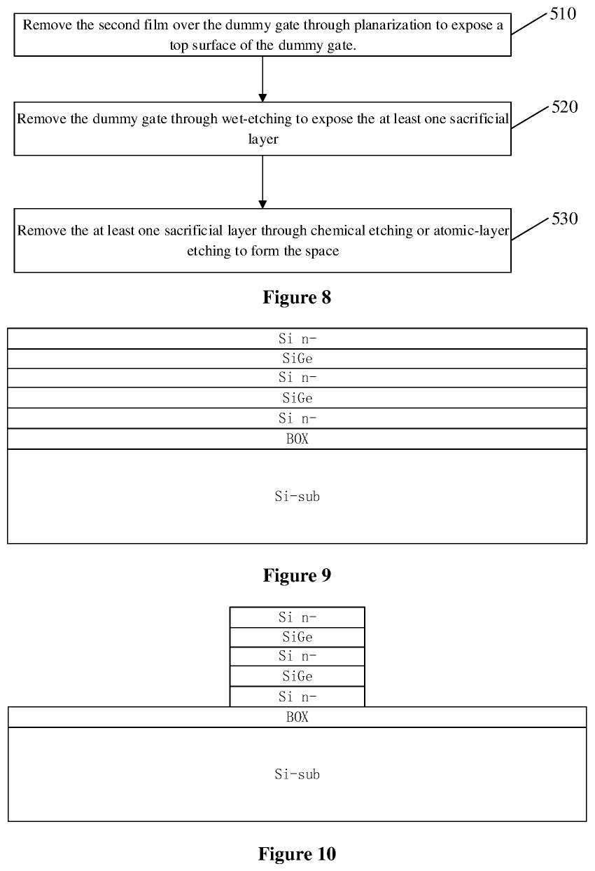

Reference is made to FIG. 8. In an embodiment, etching the dummy gate and the at least one sacrificial layer to form the space for the surrounding gate comprises steps 510 to 530.

In step 510, the second film over the dummy gate is removed through planarization to expose a top surface of the dummy gate.

In some embodiments, the top surface of the dummy gate is covered when forming the second film, and at least a part of the second film on the top surface of the dummy gate is retained after etching the second film. In such case, before etching the dummy gate, the second film covering the top surface of the dummy gate needs to be removed through planarization to expose the dummy gate, such that the dummy gate can be etched after the exposure.

In step 520, the dummy gate is removed through wet-etching to expose the at least one sacrificial layer.

In some embodiments, since the dummy gate, the first spacer, and the sacrificial layer(s) have different etching characteristics from each other, only the dummy gate may be removed in the wet-etching while without affecting the first spacer and sacrificial layer(s).

In step 530, the at least one sacrificial layer is removed through chemical etching or atomic-layer etching to form the space.

In some embodiments, the sacrificial layer(s) are located in the space surrounding the channel layer(s), and the space is partially blocked. Hence, the chemical etching or the atomic layer etching may be required to ensure successful etching on the sacrificial layer(s).

In an embodiment, fabricating the surrounding dielectric-metal gate in the space to form the gate-all-around TFET device comprises a following step. The surrounding dielectric-metal gate is formed in the space through atomic layer deposition or vapor deposition.

In some embodiments, the space is irregular around the channel layer. Hence, the atomic layer deposition or the vapor deposition may be required to fabricate the dielectric-metal gate in such space.

Reference is made to FIGS. 9 to 18, which shows an embodiment for illustrating technical solutions according to the present disclosure.

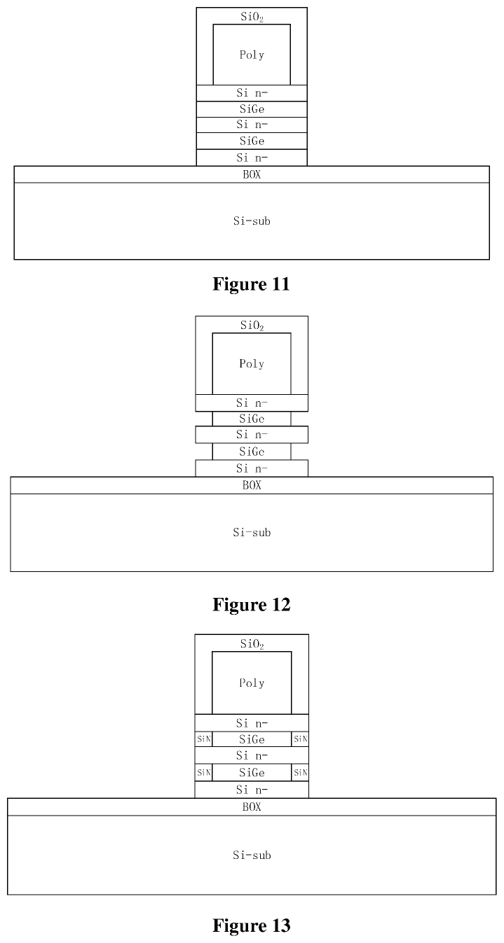

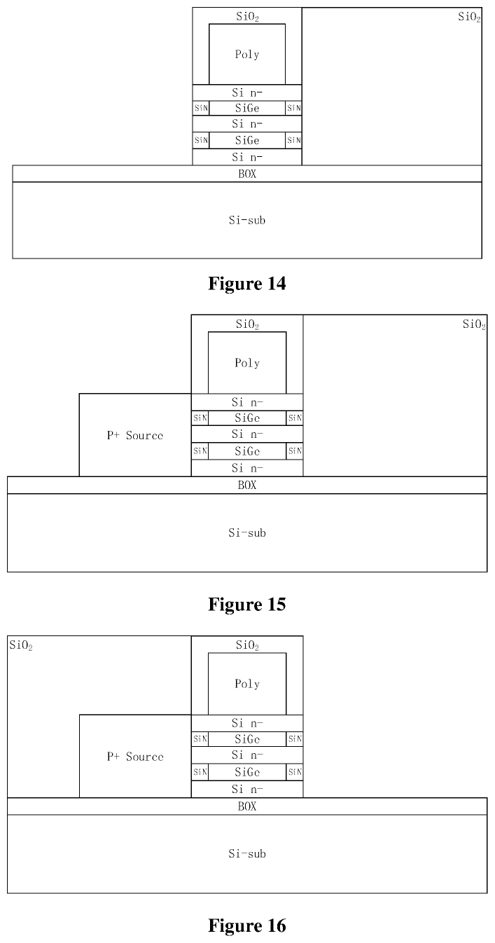

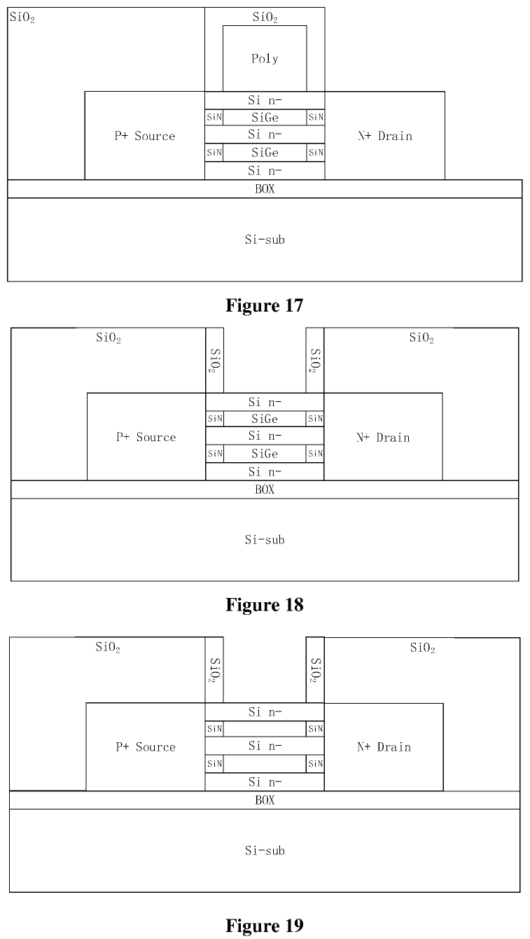

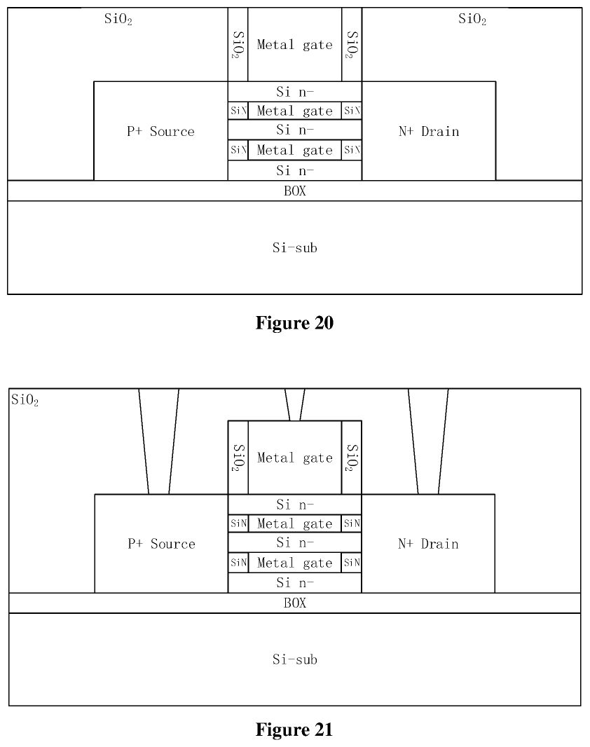

First, SiGe layer(s) and boron-doped Si layer(s) are sequentially grown on an SOI (Silicon On Insulator) wafer through epitaxy. The boron-doped Si layer(s) determines a quantity of final nanowires, and a quantity of the boron-doped Si layer(s) is at least one. In this embodiment, the SiGe layer serves as the sacrificial layer, and the boron-doped Si layer serves as the channel layer. A structure of the formed stack may be as shown in FIG. 9. It is required to perform photolithography and etching on the stack, so as to fabricate the stack into a shape meeting a requirement of the device. The etching may be implemented as, for example, dry etching. The channel stack formed through after the etching may be as shown in FIG. 10. A film, such as a polysilicon film, is deposited and then etched to form the dummy gate. Another film, such as a silicon dioxide film, is deposited and then etched to form to form the first spacer, where a structure after forming the spacer may be as shown in FIG. 11. After forming the first spacer, the sacrificial layer(s) are etched to form inward recesses, which may be as shown in FIG. 12. After forming the recesses, another film, such as a silicon nitride film, is deposited and then etched to form the second spacers, where a structure after forming the second spacers may be as shown in FIG. 13. When forming the sidewalls, anisotropic etching may be configured with high selectivity ratio. Thereby, the film along a horizontal plane can be removed quickly, while the film along the vertical plane is thinned at a lower rate during the etching. After the second spacers are formed, the structure is subject to filling with a dielectric layer, for example, a silicon dioxide layer. After the filling, photolithography is performed on the dielectric layer to expose the region for fabricating the source, where the structure may be as shown in FIG. 14. After the source region is exposed, SiGe in-situ doped with boron ions is grown at the region for fabricating the source through epitaxy, so as to form the source, where the structure may be as shown in FIG. 15. A process similar to that for forming the source is further performed, that is, the structure is subject to filling with a dielectric layer and then the dielectric layer is subject to photolithography and etching to expose the region for fabricating the drain, where the structure may be as shown in FIG. 16. After the drain region is exposed, SiGe doped with phosphor is grown in the region for fabricating the drain through epitaxy, so as to form the drain, where the structure may be as shown in FIG. 17. After forming the drain, the dielectric layer in the region for fabricating the source is removed, where the structure may be as shown in FIG. 18. After forming the source and drain, the structure is subject to filling with a dielectric layer and then planarized through, for example, chemical mechanical polishing, in order to remove the silicon dioxide film on a top surface of the dummy gate. Then, the dummy gate is removed through etching, for example, wet etching. A structure after removing the dummy gate may be as shown in FIG. 18. At such time, the sacrificial layer(s) are exposed for subsequent etching. As an example, the etching may be dry etching, wet atomic-layer etching, or hydrogen-chloride gas reaction etching. After the etching, the space once occupied by the dummy gate and the sacrificial layer(s) are vacant, where a structure may be as shown in FIG. 19. Then, a high-K dielectric-metal gate is grown in such space, that is, the surrounding dielectric-metal gate is formed, where a structure may be as shown in FIG. 20. Afterwards, a film such as a silicon dioxide film is formed, and metal plug(s) may be formed in opening(s) within such film. Thereby, the final device is fabricated, and a structure of the device may be as shown in FIG. 21.

Hereinabove described are specific embodiments of the present disclosure. The protection scope of the present disclosure is not limited thereto. Any modifications or substitutions that can be easily obtained by those skilled in the art within a technical scope disclosed herein shall fall within the protection scope of the present disclosure. Therefore, the protection scope of the present disclosure is subject to a scope of the claims.

1. A method for manufacturing a gate-all-around tunneling field-effect transistor (TFET) device, comprising:
forming, on a substrate, a channel stack comprising at least one channel layer and at least one sacrificial layer that alternate with each other;
forming, on the substrate, a dummy gate astride the channel stack;
forming a first spacer at a surface of the dummy gate;
etching the at least one sacrificial layer to form recesses on side surfaces of the channel stack;
forming second spacers in the recesses, respectively;
fabricating, on the substrate after forming the second spacers, a source and a drain separately, wherein a region for fabricating the source is shielded by a dielectric material when fabricating the drain, and a region for fabricating the drain is shielded by another dielectric material when fabricating the source; and
etching the dummy gate and the at least one sacrificial layer to form a space for a surrounding gate; and
fabricating a surrounding dielectric-metal gate in the space to form the gate-all-around TFET device.

2. The method according to claim 1, wherein forming, on the substrate, the channel stack comprising the at least one channel layer and the at least one sacrificial layer that alternate with each other comprises:
growing, on a silicon-on-insulator substrate through epitaxy, at least one layer of silicon germanium and at least one layer of boron-doped silicon that alternate with each other, wherein the at least one layer of silicon germanium serves as the at least one sacrificial layer, and the at least one layer of boron-doped silicon serves as the at least one channel layer; and
dry-etching the at least one layer of silicon germanium and the at least one layer of boron-doped silicon to form the channel stack which is a fin extending along a first direction.

3. The method according to claim 1, wherein forming, on the substrate, the dummy gate astride the channel stack comprises:
forming a first film covering a surface of the substrate and the channel stack; and
etching the first film according to a pattern of the channel stack to form the dummy gate, wherein the dummy gate and the channel stack form a stepped structure along a first direction, and the dummy gate extends across the channel stack along a second direction.

4. The method according to claim 3, wherein forming the first spacer at the surface of the dummy gate comprises:
forming a second film which covers the dummy gate, the channel stack, and the substrate, wherein etching selectivity between the second film and the first film is not equal to 1;
etching the second film to form the first spacer covering side surfaces and a top surface of the dummy gate, wherein along the first direction, two ends of the first spacer are aligned with same positions as the side surfaces, respectively, of the channel stack.

5. The method according to claim 1, wherein etching the at least one sacrificial layer to form the recesses on the side surfaces of the channel stack comprises:
etching, from the side surfaces of the channel stack, the at least one sacrificial layer to form the recesses, wherein a depth of each of the recesses is equal to a thickness of the first spacer at a side surface of the dummy gate.

6. The method according to claim 1, wherein forming the second spacers within the recesses comprises:
forming, on the side surface of the channel stack, a third film of which a thickness is more than or equal to the depth of the recesses; and
etching the third film to form the second spacers, wherein along the first direction, an outer surface of each of the second spacers is aligned with a same position as a respective sidewall of the at least one channel layer.

7. The method according to claim 1, wherein fabricating the source and the drain separately comprises:
forming a second film covering at least the region for fabricating the drain;
etching the second film to expose a top surface of the substrate in the region for fabricating the source;
growing the source, which is in-situ doped, through epitaxy on the top surface of the substrate; and
removing the second film in the region for fabricating the drain.

8. The method according to claim 1, wherein fabricating the source and the drain separately comprises:
forming a second film covering at least the region for fabricating the drain;
etching the second film to expose a top surface of the substrate in the region for fabricating the drain;
growing the drain, which is in-situ doped, through epitaxy on the top surface of the substrate; and
removing the second film in the region for fabricating the source.

9. The method according to claim 3, wherein etching the dummy gate and the at least one sacrificial layer to form the space for the surrounding gate comprises:
removing the second film over the dummy gate through planarization to expose a top surface of the dummy gate;
removing the dummy gate through wet-etching to expose the at least one sacrificial layer; and
removing the at least one sacrificial layer through chemical etching or atomic-layer etching to form the space.

10. The method according to claim 1, wherein fabricating the surrounding dielectric-metal gate in the space to form the gate-all-around TFET device comprises:
forming the surrounding dielectric-metal gate in the space through atomic layer deposition or vapor deposition.

11. An apparatus for manufacturing a gate-all-around tunneling field-effect transistor (TFET) device, comprising:
a memory storing computer-readable instructions, and
a processor, wherein the computer-readable instructions when executed by the processor configure the apparatus to perform:
forming, on a substrate, a channel stack comprising at least one channel layer and at least one sacrificial layer that alternate with each other;
forming, on the substrate, a dummy gate astride the channel stack;
forming a first spacer at a surface of the dummy gate;
etching the at least one sacrificial layer to form recesses on side surfaces of the channel stack;
forming second spacers in the recesses, respectively;
fabricating, on the substrate after forming the second spacers, a source and a drain separately, wherein a region for fabricating the source is shielded by a dielectric material when fabricating the drain, and a region for fabricating the drain is shielded by another dielectric material when fabricating the source; and
etching the dummy gate and the at least one sacrificial layer to form a space for a surrounding gate; and
fabricating a surrounding dielectric-metal gate in the space to form the gate-all-around TFET device.

12. A non-transitory computer-readable storage medium, storing computer-readable instructions, wherein the computer-readable instructions when executed by a processor configure an apparatus for manufacturing a gate-all-around tunneling field-effect transistor (TFET) device to perform:
forming, on a substrate, a channel stack comprising at least one channel layer and at least one sacrificial layer that alternate with each other;
forming, on the substrate, a dummy gate astride the channel stack;
forming a first spacer at a surface of the dummy gate;
etching the at least one sacrificial layer to form recesses on side surfaces of the channel stack;
forming second spacers in the recesses, respectively;
fabricating, on the substrate after forming the second spacers, a source and a drain separately, wherein a region for fabricating the source is shielded by a dielectric material when fabricating the drain, and a region for fabricating the drain is shielded by another dielectric material when fabricating the source; and
etching the dummy gate and the at least one sacrificial layer to form a space for a surrounding gate; and
fabricating a surrounding dielectric-metal gate in the space to form the gate-all-around TFET device.
